(19) United States
(12) Patent Application Publication
(10) Pub. No.: US 2008/0242106 A1
(43) Pub. Date: Oct. 2, 2008

(54) CHEMICAL MECHANICAL POLISHING METHOD AND APPARATUS FOR REDUCING MATERIAL RE-DEPOSITION DUE TO pH TRANSITIONS

(76) Inventor: Anuj Sarveshwar Narain, Dallas, TX (US)

Correspondence Address: TEXAS INSTRUMENTS INCORPORATED, P O BOX 655474, M/S 3999, DALLAS, TX, 75265, US

(21) Appl. No.: 11/693,307

(22) Filed: Mar. 29, 2007

(51) Int. Cl. H01L 21/31

(52) U.S. Cl. 438/759; 451/67

(57) ABSTRACT

A CMP apparatus and process reduces material re-deposition due to pH transitions. The CMP process reduces the re-deposition of material by performing a water rinse between CMP stages. A CMP apparatus, which performs CMP process, may reduce re-deposition by including a water rinse between two CMP stages that utilize different pH slurries.

### FIELD

The invention relates generally to systems and methods for semiconductor fabrication.

### BACKGROUND

Advances in electronic devices generally include reducing the size of the components that form integrated circuits. With smaller circuit components, the value of each unit area of a semiconductor wafer becomes higher. This is because the ability to use all of the wafer area for integrated circuit components improves. To properly form an integrated circuit that employs a much higher percentage of usable wafer area, it is critical that contaminant particle counts on the semiconductor wafer surface be reduced below levels which previously may have been acceptable. For example, minute particles of oxides and metals of less than 0.2 microns are unacceptable for many of the popular advanced circuit designs, because they can short out two or more conducting lines.

In order to planarize a semiconductor wafer and to remove unwanted particles, chemical mechanical polishing or chemical mechanical polish (“CMP”) process has become popular. CMP apparatus place a semiconductor wafer in contact with a polishing pad or platen that rotates relative to the semiconductor wafer. The semiconductor wafer may be stationary, or it may also rotate on a carrier that holds the wafer. The CMP apparatus utilizes a chemical compound or “slurry” in combination with the platen to remove material from the semiconductor wafer.

During CMP processes, the semiconductor wafer may experience acidity or basicity value (“pH”) transitions due to different slurries used during multiple CMP steps. These pH transitions may cause materials from the surface of a semiconductor wafer to be removed and then re-deposited onto the surface of the wafer. This phenomenon may particularly occur when the majority of the surface of the wafer is covered with a semiconductor oxide, such as silicon dioxide. Re-deposition of materials onto the surface of the wafer may results in potential yield and reliability loss. For example, if a metal is re-deposited onto the surface of the wafer, shorts may be formed between contacts or lines. Accordingly, methods and apparatus are needed to prevent re-deposition of materials onto the surface of the wafer during CMP processes.

### SUMMARY

An embodiment is directed to a method of fabricating a semiconductor device. The method comprises polishing a semiconductor wafer with a first slurry, rinsing the semiconductor wafer with water, and polishing the semiconductor wafer with a second slurry. The second slurry has a pH different from the first slurry. The rinsing the semiconductor wafer with water affects the re-deposition of a material during polishing the semiconductor wafer with the second slurry. As such, the amount of defects on the semiconductor wafer surface is reduced.

Another embodiment is directed to a method of fabricating a semiconductor device. The method comprises performing a bulk polish on a semiconductor wafer with a first slurry to remove portions of a metal from the semiconductor wafer, performing a rinse of the semiconductor wafer with water, and performing a oxide buff on the semiconductor wafer with a second slurry. The performing of the rinse of the semiconductor wafer with water affects the re-deposition of the metal during performing the oxide buff.

Another embodiment is direct to an apparatus for performing a chemical mechanical polishing (CMP). The apparatus comprises a polishing station for removing material from a surface of a semiconductor wafer utilizing a slurry and a dispenser for applying water to the surface of the semiconductor wafer. The water affects the re-deposition of the material during polishing the semiconductor wafer.

Additional embodiments of the disclosure will be set forth in part in the description which follows, and in part will be obvious from the description, or may be learned by practice of the present disclosure. The embodiments of the disclosure will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this specification, illustrate embodiments of the disclosure and together with the description, serve to explain the principles of the embodiments.

FIG. 1 is a generalized schematic illustrating a CMP apparatus consistent with embodiments of the present disclosure.

FIG. 2 is a flow diagram illustrating a CMP process consistent with embodiments of the present disclosure.

FIG. 3 is a flow diagram illustrating another CMP process consistent with embodiments of the present disclosure.

FIG. 4 is a diagram illustrating a wafer map showing defects.

### DETAILED DESCRIPTION

Embodiments of the present disclosure are directed to a CMP apparatus and process to reduce material re-deposition due to pH transitions. The CMP process reduces the re-deposition of material by performing a water rinse between CMP stages. A CMP apparatus, which performs CMP process, may reduce re-deposition by including a water rinse between two CMP stages that utilize different pH slurries. By utilizing the water rinse, re-deposition of material caused by pH shock may be reduced.

Reference will now be made in detail to the exemplary embodiments of the present disclosure, an example of which is illustrated in the accompanying drawings. Wherever possible, the same reference numbers will be used throughout the drawings to refer to the same or like parts.

In the following description, reference is made to the accompanying drawings that form a part thereof, and in which is shown by way of illustration specific exemplary embodiments which may be practiced. These embodiments are described in sufficient detail to enable those skilled in the art to practice the embodiments and it is to be understood that other embodiments may be utilized and that changes may be made without departing from the scope of the invention. The following description is, therefore, merely exemplary.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5.

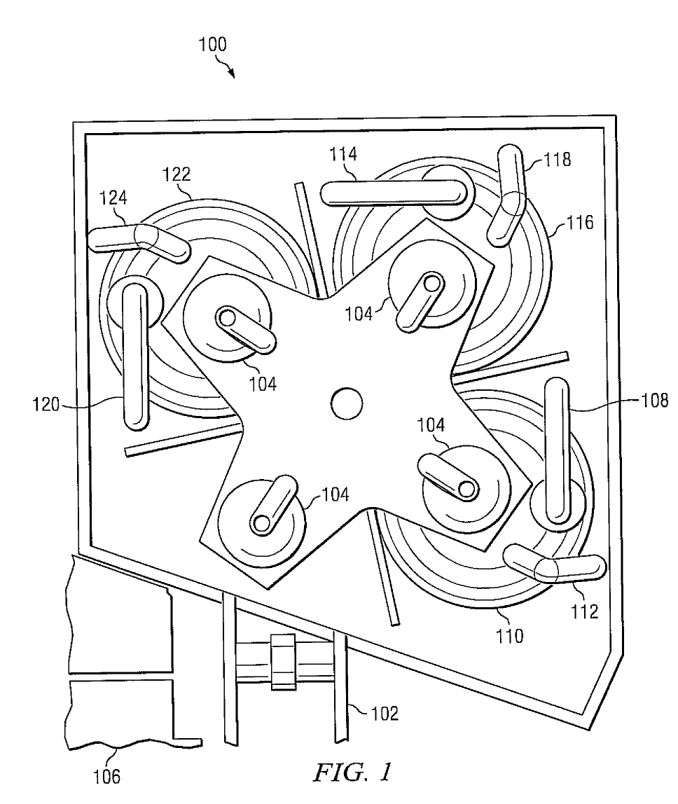

FIG. 1 is a generalized schematic diagram illustrating an exemplary CMP apparatus 100. CMP apparatus 100 comprises a loader 102, loading stations 104, a cleaner 106, wafer holders 108, 114 and 120, platens 110, 116 and 122, and slurry dispensers 112, 118 and 124. It should be readily apparent to those of ordinary skill in the art that CMP apparatus 100 illustrated in FIG. 1 represents a generalized schematic illustration and that other components may be added or existing components may be removed or modified.

CMP apparatus 100 is capable of processing multiple wafers using multiple polishing processes. CMP apparatus 100 loads wafers onto loading station 104 with loader 102. During the loading, CMP apparatus 100 may clean the wafers with cleaner 106. CMP apparatus 100 may perform any well-known cleaning process with cleaner 106.

CMP apparatus 100 processes semiconductor wafers at three polishing stations. From loader 102, CMP apparatus 100 rotates the wafer to the first polishing station comprising wafer holder 108, platen 110, and slurry dispenser 112. CMP apparatus 100 may then dispense slurry onto platen 110. The slurry may be any type of slurry depending on the type of polishing to be performed by the first polishing station.

Then, CMP apparatus 100 may polish the wafer using platen 110. Platen 110 may be any type of well-known platen utilized in any well-known CMP apparatus. CMP apparatus 100 may polish the wafer by rotating platen 110, rotating the wafer, or combinations of both.

After polishing by the first polishing station, CMP apparatus 100 may return the wafer to loading station 104. Then, CMP apparatus 100 may rotate the wafer to the second polishing station comprising wafer holder 114, platen 116, and slurry dispenser 118. CMP apparatus 100 may then dispense slurry onto platen 116. The slurry may be any type of slurry depending on the type of polishing to be performed by the second CMP station.

Then, CMP apparatus 100 may polish the wafer using platen 116. Platen 116 may be any type of well-known platen utilized in any well-known CMP apparatus. CMP apparatus 100 may polish the wafer by rotating platen 116, rotating the wafer, or combinations of both.

After polishing by the second polishing station, CMP apparatus 100 may return the wafer to loading station 104. Then, CMP apparatus 100 may rotate the wafer to the third polishing station comprising water holder 120, platen 122, and slurry dispenser 124. CMP apparatus 100 may then dispense slurry onto platen 122. The slurry may be any type of slurry depending on the type of polishing to be performed by the third CMP station.

Then, CMP apparatus 100 may polish the wafer using platen 122. Platen 122 may be any type of well-known platen utilized in any well-known CMP apparatus. CMP apparatus 100 may polish the wafer by rotating platen 122, rotating the wafer, or combinations of both.

As illustrated in FIG. 1, CMP apparatus 100 includes several wafer loading station 104. As such, CMP apparatus 100 may perform polishing on multiple wafers simultaneously. FIG. 1 illustrates CMP apparatus 100 including three polishing stations. One skilled in the art will realize that CMP apparatus 100 may include fewer or additional polishing stations.

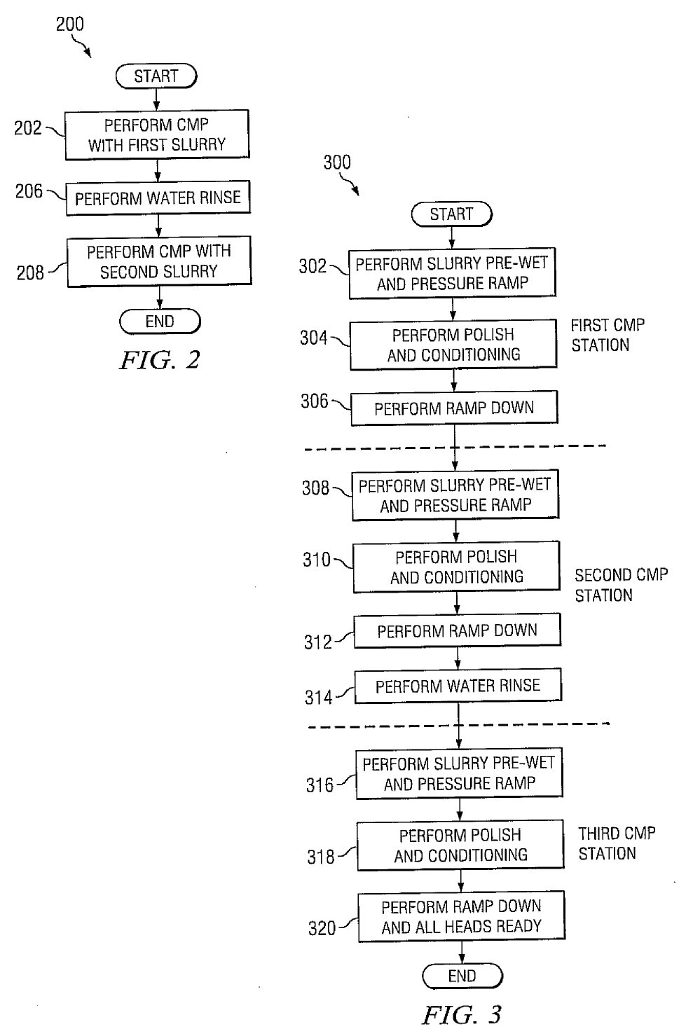

According to embodiments of the present disclosure, a CMP apparatus and process may reduce material re-deposition due to pH transitions. FIG. 2 is a flow diagram illustrating a CMP process 200 which may be performed by a CMP apparatus consistent with embodiments of the present disclosure. CMP process 200 reduces the re-deposition of material by performing a water rinse between CMP stages. A CMP apparatus, which performs process 200, may reduce re-deposition by including a water rinse between two CMP stages that utilize different pH slurries. Process 200 may be performed by any type of CMP apparatus, such as apparatus 100 illustrated in FIG. 1.

Process 200 begins with the CMP apparatus performing a CMP stage on a semiconductor wafer by utilizing a first slurry (stage 202). The polishing may be any type of CMP stage such as a bulk polish, over polish, oxide buff, and the like. The first slurry may be any type of slurry necessary for the particular type of CMP stage.

Next, the CMP apparatus performs a water rinse on the semiconductor wafer (stage 204). According to embodiments of the present disclosure, the CMP apparatus performs the water rinse in anticipation of another CMP stage being performed with a second slurry. The second slurry may differ in pH from the first slurry and may potentially cause re-deposition of a material onto the wafer. For example, the second slurry may have a higher pH than the first slurry or vice versa.

The water rinse may be performed with any type of composition of water. In particular, the CMP apparatus may perform the rinse with de-ionized (DI) water. The water rinse may be performed for any amount of time appropriate to reduce the re-deposition of material onto the wafer. In particular, the CMP apparatus may perform the water rinse for approximately 25 second or longer. Additionally, the CMP apparatus may perform the water rinse while applying pressure to the wafer from the platen. Likewise, the CMP apparatus may perform the water rinse in absence of wafer pressure.

Then, the CMP apparatus performs another CMP stage on the semiconductor wafer utilizing the second slurry (stage 206). The polishing may be any type of CMP stage such as a bulk polish, over polish, oxide buff, and the like. The first slurry may be any type of slurry necessary for the particular type of CMP stage.

In process 200 described above, the CMP apparatus may perform two CMP stages. One skilled in the art will realize that the CMP apparatus may perform additional CMP stages before and after the CMP stages described above. Further, additional water rinses may be performed between any two CMP stages in which differing pH slurries are utilized.

As mentioned above, the CMP process including a water rinse may be performed by CMP apparatus 100 illustrated in FIG. 1. FIG. 3 is a flow diagram illustrating an exemplary CMP process 300 performed by CMP apparatus 100 consistent with embodiments of the present disclosure. Process 300 consists of a bulk polish, an over polish, and an oxide buff performed by the first, second, and third polishing stations of CMP apparatus 100, respectively. According to embodiments of the present disclosure, CMP apparatus 100 performs a water rinse between the over polish and oxide buff to reduce the re-deposition of material onto the wafer.

Process 300 begins with CMP apparatus 100 performing a bulk polish. CMP apparatus 100 performs the bulk polish in order to remove a portion of a particular material from the surface of the wafer. For example, the bulk polish may be performed to remove a portion of a metal such as Tungsten (“W”). One skilled in the art will realize that a metal is exemplary and that any type of material may be removed by CMP apparatus 100.

CMP apparatus 100 begins the bulk polish by dispensing slurry onto platen 110 and ramping the pressure on the wafer from platen 110 (stage 302). CMP apparatus 100 may dispense the slurry from slurry dispenser 112. The slurry may be any type of chemical that reacts to the metal being removed in order to assist in the polishing. For example, if a metal such as W is being removed, CMP apparatus 100 may dispense a commercially available slurry, such as Cabot WS2585 or Cabot WS2000, onto platen 110.

Next, CMP apparatus 100 polishes and conditions the wafer (stage 304). CMP apparatus 100 polishes the wafer for a period of time necessary to remove the desired amount of metal. One skilled in the art will realize that the time and amount of polishing will be depend on the wafer and particular material being removed and the time and amount of polishing will be obvious to those skilled in the art.

Then, CMP apparatus 100 ramps down the pressure from platen 110 (stage 306). CMP apparatus ramps down the pressure once the desired amount of metal is removed from the wafer.

After the bulk polish is complete, CMP apparatus 100 moves the wafer to the second polishing station. CMP apparatus 100 performs an over polish at the second polishing station. CMP apparatus 100 performs the over polish to ensure that the necessary amount of metal has been removed from the wafer by removing an additional amount of metal.

CMP apparatus 100 begins the over polish by dispensing slurry onto platen 116 and ramping the pressure on the wafer from platen 116 (stage 308). CMP apparatus 100 may dispense the slurry from slurry dispenser 118. The slurry may be any type of chemical that reacts to the metal being removed in order to assist in the polishing. For example, if a metal such as W is being removed, CMP apparatus 100 may dispense a commercially available slurry, such as Cabot WS2585 or Cabot WS2000, onto platen 116.

Next, CMP apparatus 100 polishes and conditions the wafer (stage 310). CMP apparatus 100 polishes the wafer for a period of time necessary to remove the desired amount of metal. One skilled in the art will realize that the time and amount of polishing will be depend on the wafer and material being removed and the time and amount of polishing will be obvious to those skilled in the art.

Then, CMP apparatus 100 ramps down the pressure from platen 116 (stage 312). CMP apparatus 100 ramps down the pressure once the desired amount of metal is removed from the wafer.

Before performing the oxide buff, CMP apparatus 100 performs a water rinse (stage 314). CMP apparatus 100 performs the water rinse to prevent metal re-deposition during the oxide buff. During the oxide buff, the metal may be re-deposited because the slurry used during the bulk polish and over polish has a low pH value and the slurry to be used during the oxide buff has a high pH value.

CMP apparatus 100 performs a water rinse by dispensing water onto platen 116. Additionally, water may be dispensed onto the wafer. CMP apparatus 100 may dispense the water onto platen 116 from slurry dispenser 118. Likewise, CMP apparatus 100 may also be dispensed from a separate dispenser.

The water rinse may be performed with any type of composition of water. In particular, CMP apparatus 100 may perform the rinse with DI water. The water rinse may be performed for any amount of time appropriate to reduce the re-deposition of material onto the wafer. In particular, CMP apparatus 100 may perform the water rinse for approximately 25 second or longer.

Additionally, CMP apparatus 100 may perform the water rinse while applying pressure to the wafer. For example, CMP apparatus 100 may apply pressure with platen 116. Likewise, CMP apparatus 100 may perform the water rinse in the absence of wafer pressure.

After the water rinse is complete, CMP apparatus 100 moves the wafer to the third polishing station. CMP apparatus 100 performs the oxide buff at the third polishing station. CMP apparatus 100 performs the oxide buff to fix any damage caused to oxides on the wafer during the previous CMP stages.

CMP apparatus 100 begins the oxide buff by dispensing slurry onto platen 122 and ramping the pressure on the wafer with platen 122 (stage 316). CMP apparatus 100 may dispense the slurry from slurry dispenser 124. The slurry may be any type of chemical that reacts to the oxides being removed in order to assist in the polishing. For example, CMP apparatus 100 may dispense a commercially available slurry, such as Cabot SemiSpearse25, onto platen 122.

Next, CMP apparatus 100 polishes and conditions the wafer (stage 318). CMP apparatus 100 polish the wafer for a period of time necessary to remove the desired amount of oxides. One skilled in the art will realize that the time and amount of polishing will be depend on the wafer and material being removed and the time and amount of polishing will be obvious to those skilled in the art.

Then, CMP apparatus 100 ramps down the pressure and places the CMP apparatus in the all heads ready state (stage 320). CMP apparatus ramps down the pressure once the desired amount of oxide is removed from the wafer.

In process 300 described above, the water rinse is preformed by platen 116. Alternatively, CMP apparatus 100 may first move the wafer to the third polishing station and perform the water rinse with platen 122 as described above. One skilled in the art will realize that the water rinse by any of the polishing stations.

Additionally, one skilled in the art will realize that CMP apparatus 100 may perform additional CMP stages before and after the CMP stages described above. Further, additional water rinses may be performed between any two CMP stages in which differing pH slurries are utilized.

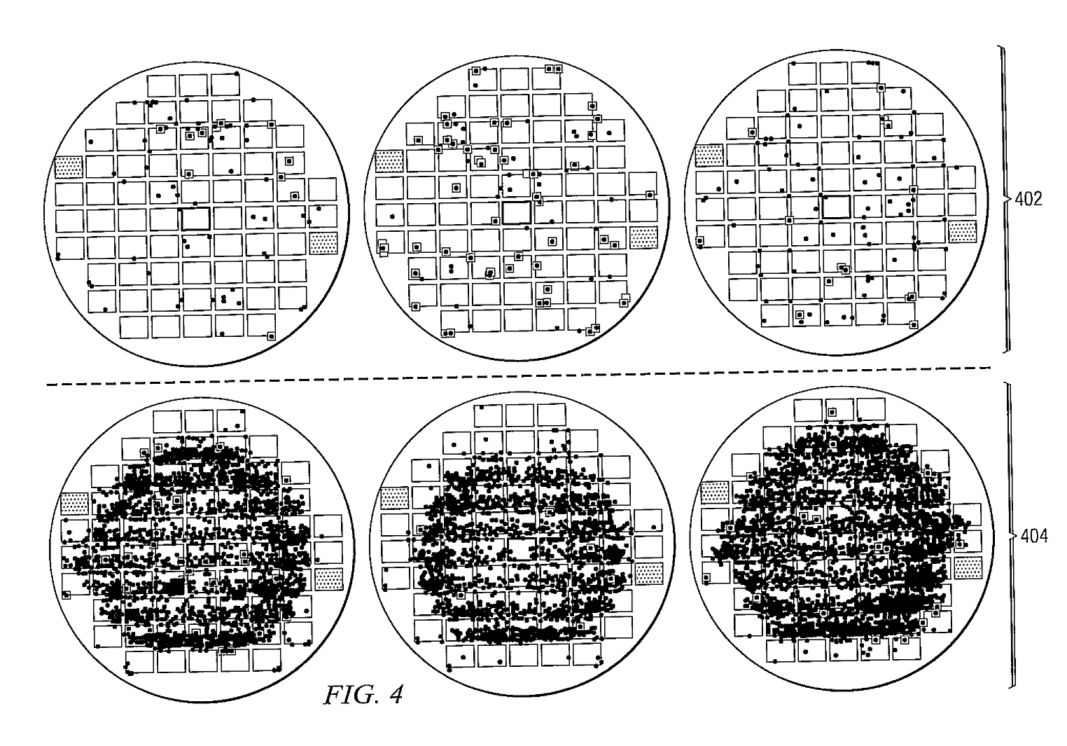

As mentioned above, the CMP apparatus and process reduces the re-deposition of material onto the wafer due to pH shock. As such, the amount of defects on the semiconductor wafer surface is reduced. FIG. 4 is a diagram illustrating wafer maps of the surface of a semiconductor wafer.

In FIG. 4, row 402 illustrates wafer maps for three CMP processes in which a water rinse is performed. Row 404 illustrates wafer maps for three CMP processes in which a water rinse is not performed. As illustrated by comparing row 402 and 404, the CMP processes, which utilize the water rinse, produce significantly less semiconductor defects on the surface of the wafer.

Other embodiments of the present teaching will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method of fabricating a semiconductor device, comprising:
polishing a semiconductor wafer with a first slurry;
rinsing the semiconductor wafer with water; and
polishing the semiconductor wafer with a second slurry, the second slurry having a pH different from the first slurry,
wherein rinsing the semiconductor wafer with water affects the re-deposition of a material during polishing the semiconductor wafer with the second slurry.

2. The method of claim 1, wherein rinsing the semiconductor wafer comprises:
applying the water to a surface of the semiconductor wafer.

3. The method of claim 2, wherein rinsing the semiconductor wafer further comprises:
applying pressure to the surface of the semiconductor wafer while applying the water to the surface of the semiconductor wafer.

4. The method of claim 1, wherein the water is de-ionized water.

5. The method of claim 1, wherein rinsing the semiconductor wafer comprises:
rinsing the semiconductor wafer for approximately 25 second or longer.

6. The method of claim 1, wherein the material is a metal.

7. A method of fabricating a semiconductor device, comprising:
performing a bulk polish on a semiconductor wafer with a first slurry to remove portions of a metal from a surface of the semiconductor wafer;
performing a rinse of the semiconductor wafer with water; and
performing a oxide buff on the surface of the semiconductor wafer with a second slurry,
wherein performing the rinse of the semiconductor wafer with water affects the re-deposition of the metal during performing the oxide buff.

8. The method of claim 7, further comprising:
performing an over polish on the semiconductor wafer prior to performing the rinse.

9. The method of claim 7, wherein performing the rinse of the semiconductor wafer comprises:
applying the water to the surface of the semiconductor wafer.

10. The method of claim 9, wherein performing the rinse of the semiconductor wafer further comprises:
applying pressure to the surface of the semiconductor wafer while applying the water to the surface of the semiconductor wafer.

11. The method of claim 7, wherein the water is de-ionized water.

12. The method of claim 7, wherein performing the rinse of the semiconductor wafer comprises:
performing the rinse of the semiconductor wafer for approximately 25 second or longer.

13. The method of claim 7, wherein the metal is tungsten.

14. The method of claim 7, wherein performing the bulk polish comprises:
dispensing the first slurry onto the surface of the semiconductor wafer; and
polishing the semiconductor wafer.

15. The method of claim 7, wherein performing the oxide buff comprises:
dispensing the second slurry onto the surface of the semiconductor wafer, and
polishing the semiconductor wafer.

16. An apparatus for performing a chemical mechanical polishing (CMP), comprising:
a polishing station for removing material from a surface of a semiconductor wafer utilizing a slurry; and
a dispenser for applying water to the surface of the semiconductor wafer,
wherein the water affects the re-deposition of the material during polishing the semiconductor wafer.

17. The apparatus of claim 16, wherein the polishing station comprises:
a wafer holder for holding the semiconductor wafer;
a platen for polishing the surface of the semiconductor wafer; and
a slurry dispenser for applying the slurry to the platen,
wherein the platen applies pressure to the surface of the semiconductor wafer in the presence of the slurry to polish the surface of the semiconductor wafer.
